(19) United States
(12) Patent Application Publication
(10) Pub. No.: US 2009/0250718 A1
(43) Pub. Date: Oct. 8, 2009

(54) LIGHT EMITTING DIODE AND METHOD FOR PRODUCING THE SAME

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/110,342

(22) Filed: Apr. 27, 2008

(30) Foreign Application Priority Data
Apr. 3, 2008 (CN) 200810066507.1

(51) Int. Cl. H01L 33/00

(52) U.S. Cl. 257/100; 438/26; 257/E33.059

(57) ABSTRACT

A method for producing an LED includes steps of: providing a base (22), a chip body (21) and a die (40), wherein the base has a concave depression (23) defined therein and the die has a bottom wall (43) with an even surface having a surface roughness not smaller than 300 nanometers; disposing the chip body in the depression; heating a material which is used to seal the chip body on the base until the material is changed into liquid; pouring the liquefied material into the depression of the base; pressing the die toward a top surface of the liquefied material until the bottom wall of the die immerges in the top surface of the liquefied material; removing the die away from the depression when the liquefied material begins to cure; and (7) curing the liquefied material until all of it is solidified.

### BACKGROUND

1. Technical Field

The present invention generally relates to a light emitting diode (LED) and a method for producing the same.

2. Description of related art

Light emitting diodes (LEDs) are a commonly used light source in applications including lighting, signaling, signage and displays. The LED has several advantages over incandescent and fluorescent lamps, including high efficacy, high brightness, long life, and stable light output. It creates much higher illuminance and space brightness with less electricity consumption.

A related LED 10 is shown in FIG. 1. The related LED 10 includes a base 12, a chip body 11 mounted on the base 12, and an encapsulation 14 sealing the chip body 11. The encapsulation 14 is made of a transparent or translucent epoxy resin and usually has a flat output surface 15.

When the output surface 15 of the LED 10 is flat, a large portion of the light emitted from the chip body 11 is reflected at the output surface 15 due to total reflection, and is not emitted to the outside. Because of this, there had been a problem in that the light extraction efficiency can not be increased.

Therefore, there is a need for an LED, which can eliminate aforesaid drawbacks. There is also a need for a method for producing the LED with low cost.

### SUMMARY

The present invention provides an LED. The LED comprises a base, a chip body and an encapsulation portion. The base has a concave depression defined therein. The chip body is disposed in the concave depression of the base. The encapsulation portion fills in the concave depression and seals the chip body on the base. The encapsulation portion has an even light output surface at a top thereof.

The present invention provides a method for producing an LED. The method comprises steps of: (1) providing a base, a chip body and a die, wherein the base has a concave depression defined therein, and the die comprises a bottom wall with an uneven surface having a surface roughness not smaller than 300 nanometers; (2) disposing the chip body in the depression; (3) heating up a material which is used to seal the chip body on the base until the material is changed into liquid; (4) pouring the liquefied material into the depression of the base; (5) pressing the die toward a top surface of the liquefied the material until the bottom wall of the die immerges into the top surface of the liquefied material; (6) removing the die away from the depression when the liquefied material begins to cure; (7) curing the liquefied material until all of the liquefied material is solidified to form an encapsulation portion sealing the chip body on the base.

Other advantages and novel features of the present invention will become more apparent from the following detailed description of preferred embodiments when taken in conjunction with the accompanying drawings.

### BRIEF DESCRIPTION OF THE DRAWINGS

FIG. 1 is an explanatory view of an LED in accordance with the related art;

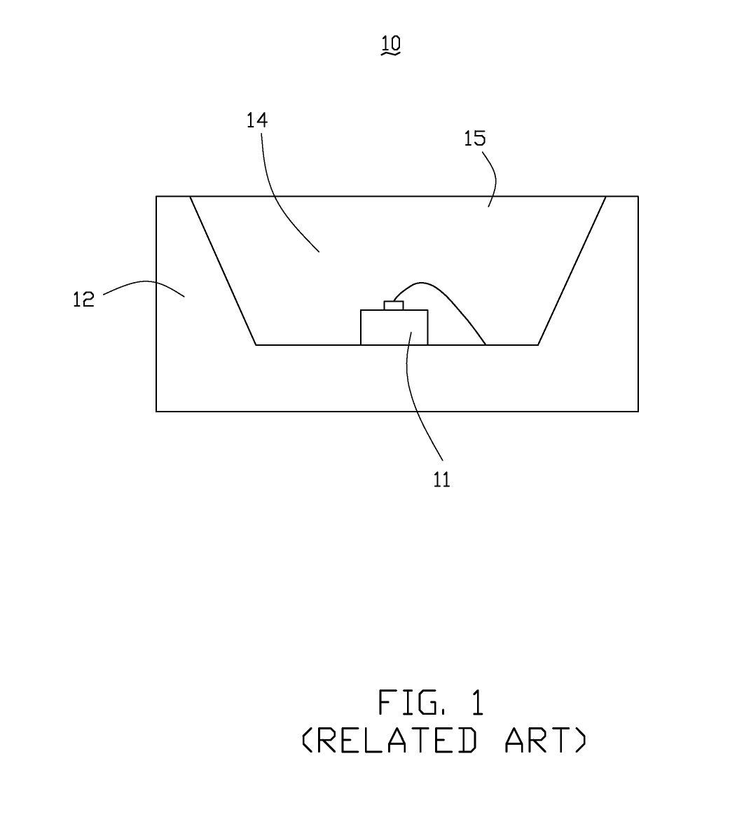

FIG. 2 is an explanatory view of an LED in accordance with an embodiment of the present invention;

FIG. 3 is an explanatory view showing a step of a method for manufacturing the LED in accordance with an embodiment of the present invention, the step including pressing a die towards a semi-finished product; and

FIG. 4 is an explanatory view showing another step of the method, which follows the step of FIG. 3.

### DETAILED DESCRIPTION

Reference will now be made to the drawing figures to describe the preferred embodiment in detail.

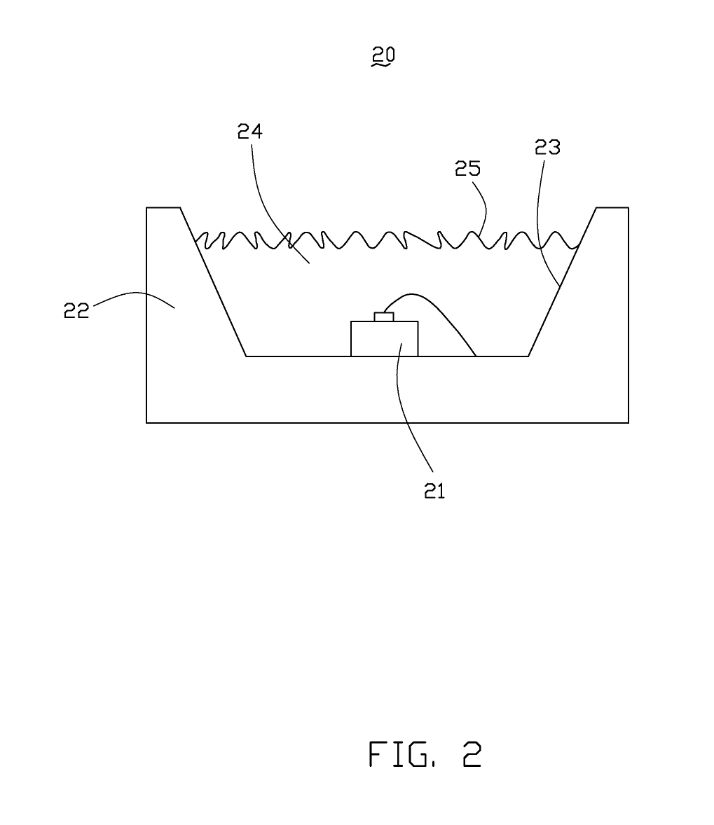

Referring to FIG. 2, a light emitting diode (LED) 20 in accordance with a preferred embodiment of the present invention is illustrated. The LED 20 comprises a base 22, a chip body 21 and an encapsulation portion 24 sealing the chip body 21 on the base 22.

The base 22 has a rectangular parallelepiped configuration, and has a concave depression 23 defined therein. The depression 23 has a flat bottom wall and a sidewall slantwise extending upwardly and outwardly from a periphery of the bottom wall.

The chip body 21 is mounted on the bottom wall of the depression 23 via a silver paste or other conventional method. The chip body 21 electrically connects to electric components (not shown) such as electrodes arranged in the base 22 so that the chip body 21 is electrically connected to a printed circuit board (not shown).

The encapsulation portion 24 serves to redirect the light from the chip body 21 in addition to protecting the chip body 21 from external physical and/or electrical shock. The encapsulation portion 24 fills in the concave depression 23 and has a light output surface 25 which is uneven. The light output surface 25 is lower than a top surface of the base 22. Preferably, the light output surface 25 has a surface roughness not smaller than 300 nanometers.

Since the light output surface 25 is uneven, when light generated at the chip body 21 reaches the light output surface 25, the reflection of the light back to the inside of LED 20 at the light output surface 25 can be decreased or even avoided. This facilitates extraction of light to the outside of the LED 20 and the light extraction efficiency of the LED 20 can be improved. Furthermore, since the light output surface 25 is lower than the top surface of the base 22, light emitted from the light output surface 25 can be reflected and redirected by an upper portion of the sidewall of the depression 23. This helps to improve the illumination efficiency of the LED 20.

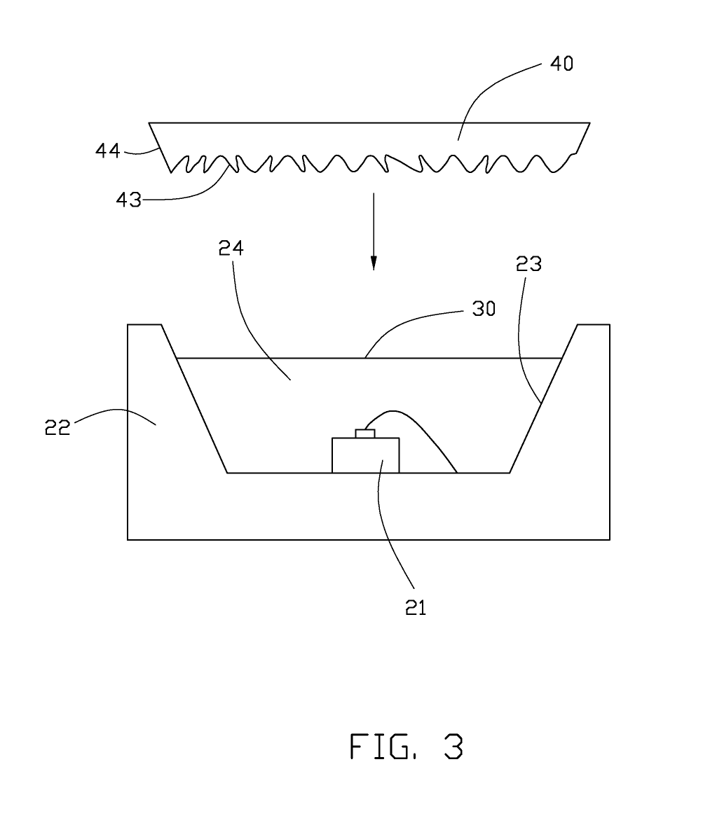

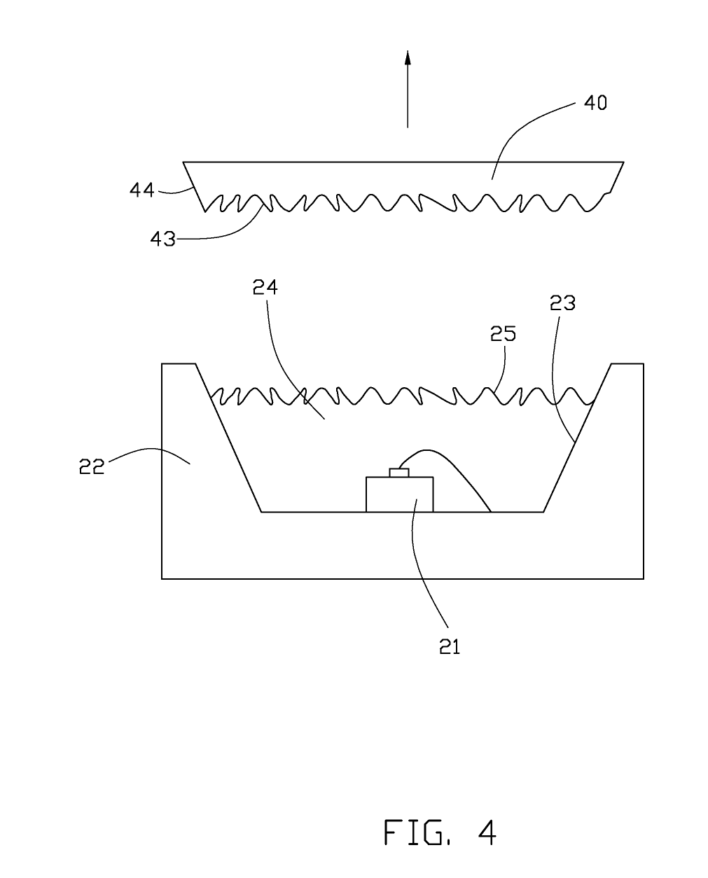

The LED 20 can be produced according to a method in accordance with a preferred embodiment of the present invention. Referring to FIGS. 3-4, this method comprises steps of:

(1) Providing a base 22, a chip body 21 and a die 40. The base 22 has a concave depression 23 defined therein and can be made of epoxy resin, glass fiber, titanium oxide, calcium oxide, or ceramic. The die 40 comprises a bottom wall 43 and a downward, inward inclined lateral wall 44 encircling the bottom wall 43. The bottom wall 43 has an uneven surface, which has a surface roughness, preferably not smaller than 300 nanometers. The lateral wall 44 is constructed to mate with an inner surface of the depression 23.

(2) Disposing the chip body 21 in the depression 23 with the chip body 21 electrically connecting to electric components (not shown) arranged in the base 22. The chip body 21 is mounted on the base 22 via a silver paste or other conventional method.

(3) Heating up a material which is used to seal the chip body 21 on the base 22 under a relatively high vacuum until the material is changed from solid into liquid. The material may be one of epoxy resin, silica gel, polyimide, acrylic and so on.

(4) Pouring the liquefied material into the depression 23 of the base 22 until a top surface 30 of the liquefied material in the depression 23 is located below the top surface of the base 22 with a predetermined distance, so as to prevent the liquefied material from overflowing out of the depression 23 in the following steps.

(5) Pressing the die 40 along a top-to-bottom direction toward the top surface 30 of the liquefied material until the bottom wall 43 of the die 40 immerges in the top surface 30 of the liquefied material;

(6) Removing the die 40 away from the depression 23 along a bottom-to-top direction as soon as the liquefied material begins to cure.

(7) Curing the liquefied material until all of the liquefied material is solidified to form the encapsulation portion 24. Then, the LED 20 is obtained.

As mentioned above, the die 40 has a very simple structure and is convenient for operation; this can reduce the production cost. Furthermore, the uneven light output surface 25 can be produced just by pressing the die 40 into the liquefied material for forming the encapsulation portion 24; this can further reduce the production cost, particularly in mass production.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A light emitting diode (LED) comprising:
a base having a concave depression defined therein;
a chip body disposed in the concave depression of the base; and
an encapsulation portion filling in the concave depression and sealing the chip body on the base, wherein the encapsulation portion has an uneven light output surface at a top thereof.

2. The LED of claim 1, wherein the depression has a flat bottom wall and a sidewall slantwise extending outwardly and upwardly from a periphery of the bottom wall of the depression, and the chip body is mounted on the bottom wall of the depression.

3. The LED of claim 2, wherein the light output surface is lower than a top surface of the base.

4. The LED of claim 3, wherein the light output surface has a surface roughness not smaller than 300 nanometers.

5. The LED of claim 1, wherein the encapsulation portion is made of a material chosen from one of epoxy resin, silica gel, polyimide, acrylic.

6. A method for producing a light emitting diode (LED) comprising steps of:
(1) providing a base, a chip body and a die, wherein the base has a concave depression defined therein, and the die comprises a bottom wall with an uneven surface;
(2) disposing the chip body in the depression;
(3) heating up a material which is used to seal the chip body on the base until the material is changed into liquid;
(4) pouring the liquefied material into the depression of the base;
(5) pressing the die toward a top surface of the liquefied material until the bottom wall of the die immerges in the top surface of the liquefied material;
(6) removing the die away from the depression when the liquefied material begins to cure; and
(7) curing the liquefied material until all of the liquefied material is solidified to form an encapsulation portion sealing the chip body on the base.

7. The method of claim 6, wherein the step (3) is carried out under a high vacuum.

8. The method of claim 6, wherein the step (4) is finished when a level of the liquefied material in the depression is below a top surface of the base with a predetermined distance so as to prevent the liquefied material from overflowing out of the depression during the process after the step (4).

9. The method of claim 6, wherein the bottom wall of the die has a surface roughness not smaller than 300 nanometers.

10. The method of claim 6, wherein the material is chosen from one of epoxy resin, silica gel, polyimide and acrylic.
